(19) United States
(12) Patent Application Publication
(10) Pub. No.: US 2011/0233674 A1
(43) Pub. Date: Sep. 29, 2011

(54) Design Structure For Dense Layout of Semiconductor Devices

(75) Inventors: Jeffrey W. Sleight, Ridgefield, CT (US); Chung-Hsun Lin, White Plains, NY (US); Josephine B. Chang, Mahopac, NY (US); Leland Chang, New York, NY (US)

(73) Assignee: International Business Machines Corporation, Armonk, NY (US)

(21) Appl. No.: 12/748,761

(22) Filed: Mar. 29, 2010

(51) Int. Cl. H01L 29/786; H01L 21/336; G06F 17/50

(52) U.S. Cl. 257/347; 438/151; 257/E21.411; 257/E29.273; 716/104

(57) ABSTRACT

A semiconductor structure, and a method of making, includes: a substrate; and at least one layer of silicon overlying the substrate, the layer of silicon including at least one active region having at least one device, a design layout of the active region in accordance with design layout rules including: a multiple-fingered device is mapped to a symmetric device or an asymmetric body-tied device; a single-fingered device is mapped to an asymmetric device; an active region having a single-fingered device is entirely source-up or source-down; and an active region falls into one of two categories: the active region does not include any symmetric devices or the active region does not include any asymmetric devices. In another exemplary embodiment, a design structure tangibly embodied on a computer readable medium, for use by a machine in the design, manufacture or simulation of an integrated circuit having the above semiconductor structure.

### TECHNICAL FIELD

The present invention relates generally to a method, device, computer program and design structure and, more specifically, relate to a design structure for semiconductor devices.

### BACKGROUND

Semiconductors and integrated circuit chips have become ubiquitous within many products due to their continually decreasing cost and size. In the microelectronics industry as well as in other industries involving construction of microscopic structures (e.g., micromachines, magnetoresistive heads, etc.) there is a continued desire to reduce the size of structural features and microelectronic devices and/or to provide a greater amount of circuitry for a given chip size. Miniaturization in general allows for increased performance (more processing per clock cycle and less heat generated) at lower power levels and lower cost. Present technology is at or approaching atomic level scaling of certain micro-devices such as logic gates, FETs and capacitors, for example. Circuit chips with hundreds of millions of such devices are not uncommon. Further size reductions appear to be approaching the physical limit of trace lines and micro-devices that are embedded upon and within their semiconductor substrates. The present invention is directed to such micro-sized devices.

Basically, a FET is a transistor having a source, a gate, and a drain. The action of the FET depends on the flow of majority carriers along a channel between the source and drain that runs past the gate. Current through the channel, which is between the source and drain, is controlled by the transverse electric field under the gate.

As known to those skilled in the art, p-type FETs (pFETs) turn ON to allow current flow from source to drain when the gate terminal is at a low or negative potential with respect to the source. When the gate potential is positive or the same as the source, the p-type FET is OFF, and does not conduct current. On the other hand, n-type FETs (nFETs) turn ON to allow current flow from source to drain when the gate terminal is high or positive with respect to the source. When the gate potential is negative or the same as the source, the n-type FET is OFF, and does not conduct current. Note that in each of these cases there is a threshold voltage (e.g., at the gate terminal) for triggering actuation of the FET.

More than one gate (multi-gate) can be used to more effectively control the channel. The length of the gate determines how fast the FET switches, and can be about the same as the length of the channel (i.e., the distance between the source and drain). Multi-gate FETs are considered to be promising candidates to scale complementary metal-oxide semiconductor (CMOS) FET technology down to the sub-22 nm regime. However, such small dimensions necessitate greater control over performance issues such as short channel effects, punch-through, metal-oxide semiconductor (MOS) leakage current and, of particular relevance herein, the parasitic resistance that is present in a multi-gate FET.

The size of FETs has been successfully reduced through the use of one or more fin-shaped channels. A FET employing such a channel structure may be referred to as a FinFET. Previously, CMOS devices were substantially planar along the surface of the semiconductor substrate, the exception being the FET gate that was disposed over the top of the channel. Fins break from this paradigm by using a vertical channel structure in order to maximize the surface area of the channel that is exposed to the gate. The gate controls the channel more strongly because it extends over more than one side (surface) of the channel. For example, the gate can enclose three surfaces of the three-dimensional channel, rather than being disposed only across the top surface of the traditional planar channel.

One technique for affecting the threshold voltage (e.g., increasing the threshold voltage, encouraging a more constant threshold voltage over different gate lengths) is to use locally implanted dopants under the gate edge(s). This is referred to as a “halo” implant. As non-limiting examples, the halo implant may include arsenic, phosphorous, boron and/or indium.

In the fabrication of semiconductor devices, the vertical arrangement of FET components, namely the source and drain elements, can be altered. For example, a given FET may have the source located at or towards a top portion of the device (so-called “source up”). As another example, a given FET may have the source located at or towards a bottom portion of the device (so-called “source-down”). For a source-up FET, the source implant is from the top of the device. For a source-down FET, the source implant is from the bottom of the device. In some semiconductor devices that combine multiple FETs within a single device, the device may include both source-up FETs and source-down FETs. Since the arrangement of the regions in such a device are not entirely coincident, multiple masks and additional processing steps are needed to fabricate the device.

Silicon-on-insulator (SOI) wafers have been used to exploit the improved quality of monocrystalline silicon provided thereby in an active layer formed on an insulator over a bulk silicon “handling” substrate. Similar attributes can be developed in similar structures of other semiconductor materials and alloys thereof. The improved quality of the semiconductor material of the active layer allows transistors and other devices to be scaled to extremely small sizes with good uniformity of electrical properties.

Unfortunately, the existence of the insulator layer which supports the development of the improved quality of semiconductor material also presents a problem known in the art as floating body effect in transistor structures. The floating body effect is specific to transistors formed on substrates having an insulator layer. The neutral floating body is electrically isolated by source/drain and halo extension regions that form oppositely poled diode junctions at the ends of the transistor conduction channel and floating body while the gate electrode is insulated from the conduction channel through a dielectric. The insulator layer in the substrate completes insulation of the conduction channel and thus prevents discharge of any charge that may develop in the floating body. Charge injection into the neutral body when the transistor is not conducting develops voltages in the conduction channel in accordance with the source and drain diode characteristics.

One approach to reduction of floating body effects is to use body contacts to form a connection from the floating body/conduction channel to the source electrode through the impurity well. In some cases, the body contact effectively ties the body of the FET to ground. This approach is only a partial solution since the well can be highly resistive and the connection can be ineffective. Further, the connection requires additional chip space and, therefore, may affect or preclude achievement of the potential integration density that would otherwise be possible. This type of device may be referred to as a “body-tied” FET, and may be P-type or N-type.

While many designs for FETs are symmetrical, the use of asymmetric devices (e.g., asymmetric or asymmetrical FETs or MOSFETs) has become prevalent, for example, in SOI CMOS technologies. In such asymmetric devices there is a preferred direction for majority charge carrier flow. As an example, this preference may be due to different dopings of or in relation to (i.e., relative to) the source and drain regions, such as different implant dosages or asymmetric implant(s) (e.g., asymmetric source and/or drain extension implants, asymmetric halo implants) relative to the gate channel conductor. Asymmetric devices can provide advantages of increased drive currents and reduced parities. As a non-limiting example, asymmetric extension and halo devices can be fabricated by using angled implants and by using the (possibly dummy) gate to mask the source or drain region (e.g., due to shadowing by the gate structure).

However, a problem arises in scaling these asymmetric devices to groundrules associated with 45 nm technologies and beyond. In that these devices typically offer a significant performance increase (e.g., about 7-15%) from both floating body control and Miller capacitance reduction, the potential loss of this performance for future CMOS technology presents a significant impediment to future development.

### BRIEF SUMMARY

In one aspect, exemplary embodiments of the invention provide a semiconductor structure comprising: a substrate; and at least one layer of silicon overlying the substrate, the at least one layer of silicon comprising at least one active region having at least one device, where a design layout of the at least one active region is in accordance with a plurality of design layout rules comprising: a multiple-fingered device is mapped to be a symmetric device or an asymmetric body-tied device; a single-fingered device is mapped to be an asymmetric device; an active region having a single-fingered device is entirely source-up or entirely source-down; and an active region falls into one of two categories: a first category where the active region does not include any symmetric devices or a second category where the active region does not include any asymmetric devices.

In another aspect, exemplary embodiments of the invention provide a method for forming a semiconductor structure, comprising: defining at least one active region within at least one layer of silicon overlying a substrate; and fabricating at least one device within the at least one active region in accordance with a plurality of design layout rules comprising: a multiple-fingered device is mapped to be a symmetric device or an asymmetric body-tied device; a single-fingered device is mapped to be an asymmetric device; an active region having a single-fingered device is entirely source-up or entirely source-down; and an active region falls into one of two categories: a first category where the active region does not include any symmetric devices or a second category where the active region does not include any asymmetric devices.

In another aspect, exemplary embodiments of the invention provide a computer readable storage medium storing a design structure readable by a machine, the design structure comprising information representative of at least one semiconductor structure having at least one active region with at least one device, where the design structure is for use by the machine in design, manufacture or simulation of an integrated circuit, where a design layout of the at least one active region is in accordance with a plurality of design layout rules comprising: a multiple-fingered device is mapped to be a symmetric device or an asymmetric body-tied device; a single-fingered device is mapped to be an asymmetric device; an active region having a single-fingered device is entirely source-up or entirely source-down; and an active region falls into one of two categories: a first category where the active region does not include any symmetric devices or a second category where the active region does not include any asymmetric devices.

### BRIEF DESCRIPTION OF THE SEVERAL VIEWS OF THE DRAWINGS

The foregoing and other aspects of embodiments of this invention are made more evident in the following Detailed Description, when read in conjunction with the attached Drawing Figures, wherein:

FIG. 1 shows a cross-sectional view of an exemplary active region wherein a single-fingered device is mapped to be an asymmetric device in accordance with the exemplary embodiments of the invention;

FIG. 2 shows an exemplary active region wherein a multi-fingered device is mapped to be a symmetric device in accordance with the exemplary embodiments of the invention;

FIG. 3 depicts an exemplary semiconductor structure in accordance with the exemplary embodiments of the invention;

FIG. 4 shows a flow diagram of an exemplary design process used in semiconductor design, manufacture and/or test in accordance with the exemplary embodiments of the invention;

FIG. 5 illustrates a block diagram of an exemplary system in which certain exemplary embodiments of the invention may be implemented;

FIG. 6 depicts a flowchart illustrating one non-limiting example of a method for practicing the exemplary embodiments of this invention; and

FIG. 7 depicts a flowchart illustrating another non-limiting example of a method for practicing the exemplary embodiments of this invention.

### DETAILED DESCRIPTION OF THE PREFERRED EMBODIMENTS

The exemplary embodiments of the invention provide methods, semiconductor structures and design structures that utilize new design layout rules to achieve increased density and reduced manufacturing costs. In conjunction with newer fabrication techniques and semiconductor designs, the design layout rules presented below enable manufacturers to realize various improvements over conventional production techniques and devices.

In one exemplary embodiment, the design layout rules are for at least one active region on the device and include the following rules:
(A) A multiple-fingered device is mapped to be a symmetric device or an asymmetric body-tied device;
(B) A single-fingered device is mapped to be an asymmetric device;
(C) An active region having a single-fingered device is entirely source-up or entirely source-down; and
(D) An active region falls into one of two categories: a first category where the active region does not include any symmetric devices or a second category where the active region does not include any asymmetric devices.

As utilized herein, the terms symmetric and asymmetric should be understood to refer to the production of the device and not the behavior of the device. For example, a symmetric device may be equally doped in the source and drain regions, and, thus, may not utilize an angled implant (e.g., for asymmetric source/drain extensions) during its production. As another example, and as further discussed in U.S. patent application Ser. Nos. 12/683,606 and 12/683,634 (see below), an asymmetric body-tied FET behaves as if it were a symmetric device. Even so, an asymmetric body-tied FET is still considered an asymmetric device for the purposes of the exemplary embodiments of this invention since the asymmetric body-tied FET is (e.g., is produced as) an asymmetric device regardless of its behavior and/or operation. For purposes of clarity, rule (B) explicitly refers to an asymmetric body-tied device since such a device will function/operate as a symmetric device (see below).

Rule (A) avoids the need for a block mask for both a source-up and a source-down configuration within a same active region, thus reducing manufacturing costs. Furthermore, rule (A) avoids an area penalty that would otherwise be incurred.

As noted in U.S. patent application Ser. Nos. 12/683,606 and 12/683,634, it has been observed that a body-tied asymmetric device behaves as a symmetric device. As a non-limiting example, pass gates needs a symmetric device for proper operation. For rule (B), if a pass gate or other such element (i.e., one that requires a symmetric device or a device that behaves as a symmetric device) is to be included within a single-fingered device, an asymmetric device could be body-tied in order to enable operation as a symmetric device. In such a manner, rule (B) would be maintained despite the seemingly contrary requirement of the pass gate. While the body-tie would consume some area, the layout could still be packed, for example, by alternating the stack orientation. This layout area loss may be less than other alternatives such as dual gate pitch, for example.

Rule (C) means there is no mixing of source-up and source-down components. Furthermore, rule (C) implies that the groundrules that govern reception-to-reception spacing (e.g., spacing between active regions) would similarly govern other spacings (e.g., between various ones of source-up nFETs, source-down nFETs, source-up pFETs and source-down pFETs).

Rule (D) avoids mixing of device types (symmetric and asymmetric) within a same active region. This is in contravention to conventional architectures wherein the types are mixed. Rule (D) enables a larger spacing between the normal halo mask (i.e., for symmetric devices) and the asymmetric halo mask (i.e., for asymmetric devices), ensuring that the different elements do not interact with one another (e.g., which could occur without sufficient space between the elements).

It is noted that this patent application is related to commonly-assigned U.S. patent application Ser. No. 12/683,606, filed Jan. 7, 2010, and to commonly-assigned U.S. patent application Ser. No. 12/683,634, filed Jan. 7, 2010, the disclosures of which are incorporated by reference herein in their entireties.

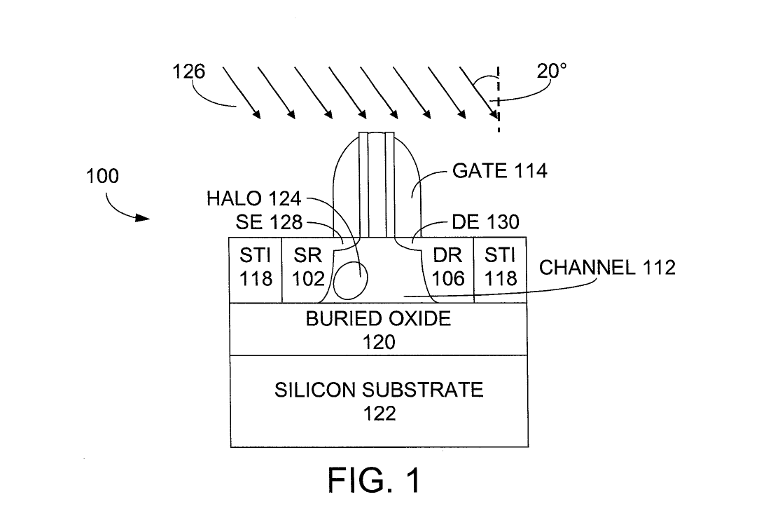

As understood by one of ordinary skill in the art, the terms “source-up” and “source-down” refer to aspects of manufacturing and production. For example, a source-up technique may be one wherein the device of FIG. 1 (as discussed below) is rotated about 90° clockwise (about an axis perpendicular to the view shown in FIG. 1) during fabrication (e.g., for purposes of ion implantation). In this example, the device is rotated such that the SR 102 is “upwards” while the DR 106 is “downwards.” As an example, the angled implant 126 may be performed on such a rotated device in order to achieve a particular implant. As another example, the rotation may be conducive to the formation and/or production of one or more layers and/or elements for the device.

FIG. 1 shows a cross-sectional view of an exemplary active region wherein a single-fingered device is mapped to be an asymmetric device in accordance with the exemplary embodiments of the invention. The FET 100 has a source region (SR) 102 and a drain region (DR) 106 located within an active region of the FET 100. The SR 102 and DR 106 are coupled to one another via a channel 112. A gate structure (gate) 114 overlies at least a portion of the channel 112. As with a conventional FET, current through the channel 112 is controlled by the transverse electric field under the gate 114. In some exemplary embodiments, the FET 100 may include a body contact (not shown) for a body-tie (also not shown). The body contact would be coupled to the channel 112. A halo implant (Halo 124) is disposed in the channel 112, for example, closer to the SR 102 than the DR 106. This asymmetrical doping may be accomplished via an angled implant 126 (e.g., an angled halo implant), for example, that uses the gate 114 to at least partially mask the DR 106. The body-tie (e.g., via the body contact) may be used to apply any desired bias in order to control the body potential (e.g., the accumulation and/or discharge of charge built up in the channel/floating body). As a non-limiting example, the body-tie may be connected to ground. The FET 100 optionally may include source and/or drain extension implants. The FET 100 also includes a shallow trench isolation (STI) 118. Furthermore, the FET 100 overlies (e.g., is disposed on) a buried oxide layer 120. The buried oxide layer 120 overlies a substrate 122 (e.g., a silicon substrate).

The halo 124 may be located (e.g., disposed) at least partially within the channel 112. As a non-limiting example, the halo 124 may be formed using an angled halo implant 126. As a further non-limiting example, the angled halo implant 126 may be at an angle of 1-89° (relative to a vertical axis, relative to an axis normal to an overall, general surface of the FET 100), preferably an angle of about (e.g., approximately, substantially) 10-30°, and even more preferably an angle of about (e.g., approximately, substantially) 20°. As can be seen in FIG. 1, the angled halo implant 126 may utilize the gate 114 in order to at least partially mask the DR 106 from the angled halo implant 126. This results in the FET 100 being asymmetric since the halo 124 is disposed closer to the SR 102 than the DR 106.

As shown in FIG. 1, the FET 100 optionally may include source and/or drain extension implants (SE 128 and DE 130, respectively). These extension implants may be formed using an angled implant (e.g., at an angle of 1-89° (relative to a vertical axis, relative to an axis normal to an overall, general surface of the FET 100)). As a non-limiting example, such an angled implant may utilize the gate 114 in order to at least partially mask the DR 106 from the angled implant (e.g., 126). Note that the SE 128 and DE 130 shown in FIG. 1 are symmetric (e.g., in size and/or doping). Further note that the halo 124 is disposed entirely within the channel 112. In other exemplary embodiments, the source/drain extension implants may be asymmetric and/or the halo may be disposed only partially within the channel 112. When the source/drain extension implants are symmetric, they may be formed using a vertical implant as opposed to an angled implant.

Other exemplary embodiments of the invention may include asymmetric source/drain extension implants with the halo implant entirely disposed within the channel. Similarly, still further exemplary embodiments of the invention may include symmetric source/drain extension implants with the halo implant partially disposed within a region. Any suitable combination of features and locations and arrangements thereof may be utilized in conjunction with the exemplary embodiments of the invention.

As non-limiting examples, the halo implant may comprise (e.g., be doped with) one or more of As and P. As non-limiting examples, the source/drain regions may comprise (e.g., be doped with) one or more of B and BF₂. As non-limiting examples, the source/drain extension implants may comprise (e.g., be doped with) one or more of B and BF₂.

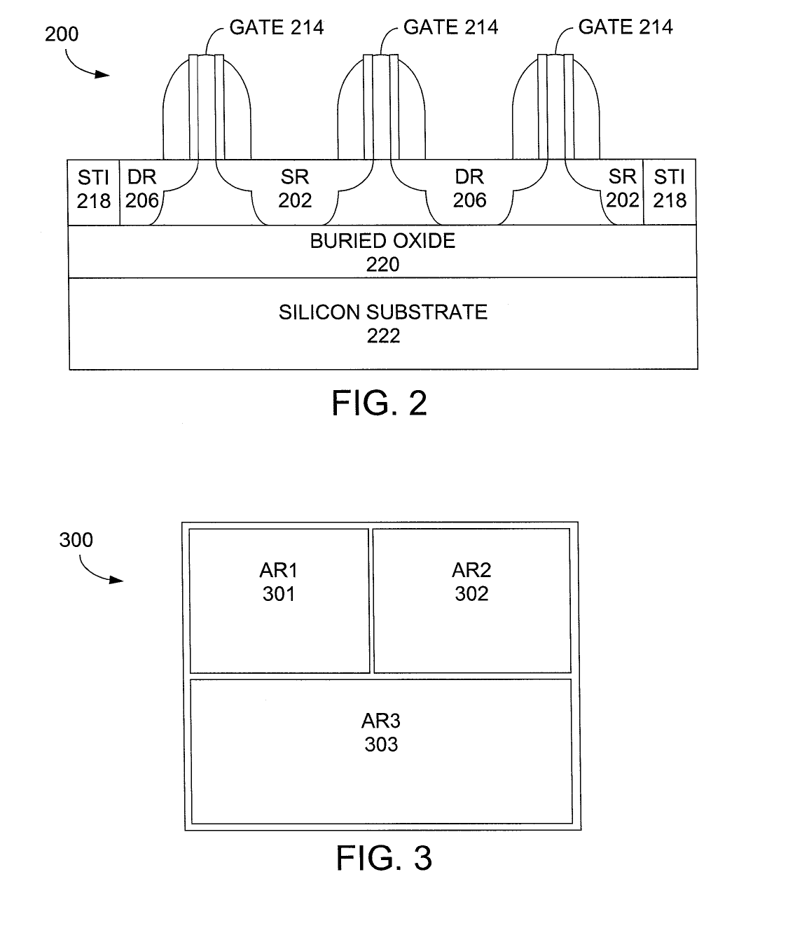

FIG. 2 shows an exemplary active region 200 wherein a multi-fingered device is mapped to be a symmetric device in accordance with the exemplary embodiments of the invention. The active region 200 includes a multi-fingered arrangement comprised of a plurality of symmetric FETs 200, each with a SR 202, a DR 206 and a gate 214. Different FETs 200 may share a single SR 202 or DR 206. The active region 200 may be delineated by a STI 218 and overlies a buried oxide layer 220 which itself overlies a silicon substrate 222. Note that a halo implant is not included since the FETs 200 are symmetric. Thus, the exemplary active region is in accordance with the rule that a multiple-fingered device be mapped to be a symmetric device. Furthermore, the active region does not include any asymmetric devices.

One of ordinary skill in the art will appreciate that any suitable component or device may be utilized. As a non-limiting example, the exemplary FETs shown above may comprise one or more N-type FETs or one or more P-type FETs. The components used and particular arrangement thereof may be implementation-specific, for example.

FIG. 3 depicts an exemplary semiconductor structure 300 in accordance with the exemplary embodiments of the invention. As shown, the exemplary semiconductor structure 300 includes a plurality of active regions (AR1 301, AR2 302, AR3 303), each having a design layout in accordance with the plurality of design layout rules described herein. As a non-limiting example, the active regions may be separated by one or more shallow trench isolations (STIs).

Exemplary embodiments of the invention may be embodied as a design of an integrated circuit (IC) chip, a core/macro for an application-specific integrated circuit (ASIC) and/or other design-related structure that is to be applied to a semiconductor wafer. As a non-limiting example, exemplary embodiments of the invention may comprise a design data file, for example, as an input to an IC design process including EDA tools, place and route tools, DRC, characterization and/or synthesis. As a further non-limiting example, exemplary embodiments of the invention may comprise a completed design file output from such tools and/or usable as an input to develop one or more masks used to fabricate the ICs. As additional non-limiting examples, exemplary embodiments of the invention may be embodied within one or more design files and/or design structures (e.g., GDSII, GL1 or OASIS data files).

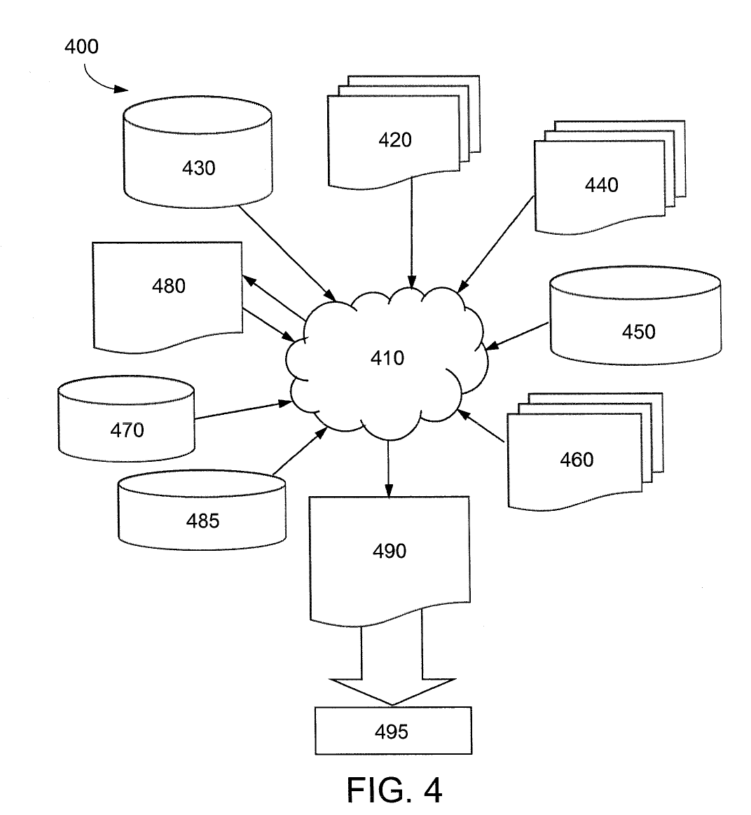

FIG. 4 shows a block diagram of an exemplary design flow 400 used, for example, in semiconductor IC logic design, simulation, test, layout and/or manufacture. The exemplary design flow 400 includes processes, machines and/or mechanisms for processing design structures or devices to generate logically or otherwise functionally equivalent representations of the exemplary design structures and/or exemplary devices (such as those described above and shown in FIGS. 1-3, for example). The design structures processed and/or generated by the design flow 400 may be encoded on machine-readable transmission or storage media (e.g., storage devices, computer-readable memory media, computer-readable storage media) to include data and/or instructions that, when executed or otherwise processed on a data processing system, generate a logically, structurally, mechanically and/or otherwise functionally equivalent representation of hardware components, circuits, devices and/or systems. Machines include, but are not limited to, any machine used in an IC design process, such as designing, manufacturing and/or simulating a circuit, component, device and/or system. For example, machines may include one or more of the following: lithography machines, machines and/or equipment for generating masks (e.g., e-beam writers), computers and/or equipment for simulating design structures, any apparatus used in the manufacturing and/or test process and/or any machines used for programming functionally equivalent representations of the design structures into any medium (e.g., a machine for programming a programmable gate array).

The design flow 400 may vary depending on the type of representation being designed. For example, a design flow 400 for building an ASIC may differ from a design flow 400 for designing a standard component or from a design flow 400 for instantiating the design into a programmable array, such as a programmable gate array (PGA) or a field programmable gate array (FPGA) offered by Altera® Inc. or Xilinx® Inc., for example.

FIG. 4 illustrates multiple such design structures including an input design structure 420 that is preferably processed by a design process 410. The design structure 420 may be a logical simulation design structure generated and processed by the design process 410 to produce a logically equivalent functional representation of a hardware device. The design structure 420 may also or alternatively comprise data and/or program instructions that, when processed by the design process 410, generate a functional representation of the physical structure of a hardware device (such as one of the devices shown in FIGS. 1-3, for example). Whether representing functional and/or structural design features, the design structure 420 may be generated using electronic computer-aided design (ECAD) such as may be implemented by a core developer/designer. When encoded on a machine-readable data transmission, gate array and/or storage medium, the design structure 420 may be accessed and processed by one or more hardware and/or software modules within the design process 410 to simulate or otherwise functionally represent an electronic component, circuit, electronic or logic module, apparatus, device and/or system, such as those shown in FIGS. 1-3, as non-limiting examples. As such, the design structure 420 may comprise one or more files and/or other data structures including human and/or machine-readable source code, compiled structures and/or computer-executable code structures (e.g., program code, program instructions, a computer program) that, when processed by a design or simulation data processing system, functionally simulate or otherwise represent circuits and/or other levels of hardware logic design. Such data structures may include hardware-description language (HDL) design entities and/or other data structures conforming to and/or compatible with lower-level HDL design languages, such as Verilog and VHDL, and/or higher level design languages, such as C or C++.

The design process 410 preferably employs and incorporates hardware and/or software modules for synthesizing, translating or otherwise processing a design/simulation functional equivalent of the exemplary components, circuits, devices and/or logic structures (e.g., one or more of those shown in FIGS. 1-3) to generate a netlist 480 which may contain design structures such as a design structure 420. The netlist 480 may comprise, for example, compiled or otherwise processed data structures representing one or more of, as non-limiting examples, a list of wires, discrete components, logic gates, control circuits, I/O devices and/or models that describe the connections to other elements and circuits in an integrated circuit design. The netlist 480 may be synthesized using an iterative process in which the netlist 480 is resynthesized one or more times depending on design specifications and parameters for the device. As with other design structure types described herein, the netlist 480 may be recorded on a machine-readable data storage medium or programmed into a programmable gate array. The medium may be a non-volatile storage medium such as a magnetic or optical disk drive, a programmable gate array, a compact flash or other flash memory. Additionally, or in the alternative, the medium may be a system or cache memory, buffer space or electrically or optically conductive devices and materials on which data packets may be transmitted and intermediately stored via the Internet and/or other networking suitable means.

The design process 410 may include hardware and/or software modules for processing a variety of input data structure types including the netlist 480. Such data structure types may reside, for example, within library elements 430 and include a set of commonly used elements, circuits and/or devices, including models, layouts and/or symbolic representations, for a given manufacturing technology (e.g., different technology nodes, 32 nm, 45 nm, 90 nm). The data structure types may further include design specifications 440, characterization data 450, verification data 460, design rules 470 and/or test data files 485 which may include input test patterns, output test results and/or other testing information. The design process 410 may further include, for example, standard mechanical design processes such as stress analysis, thermal analysis, mechanical event simulation and/or process simulation for operations such as casting, molding and die press forming. One of ordinary skill in the art of mechanical design will appreciate the extent of possible mechanical design tools and applications used in the design process 410 without deviating from the scope and spirit of the invention. The design process 410 may also include one or more modules for performing standard circuit design processes such as timing analysis, verification, design rule checking and/or place and route operations.

The design process 410 employs and incorporates logic and physical design tools, such as HDL compilers and simulation model build tools, for example, to process the design structure 420 together with some or all of the depicted supporting data structures along with any additional mechanical design or data (if applicable) to generate a second (output) design structure 490. The second design structure 490 resides on a storage medium or programmable gate array in a data format used for the exchange of data of mechanical devices and structures (e.g., information stored in an IGES, DXF, Parasolid XT, JT, DRG or any other suitable format for storing or rendering such mechanical design structures). Similar to the input design structure 420, the second design structure 490 preferably comprises one or more files, data structures and/or other computer-encoded data or instructions that reside on transmission or data storage media and that, when processed (e.g., by an ECAD system), generate a logically or otherwise functionally equivalent form of one or more of the exemplary embodiments of the invention (such as those shown in FIGS. 1-3, for example). In one exemplary embodiment, the design structure 490 may comprise a compiled, executable HDL simulation model that functionally simulates one or more of the exemplary devices in accordance with the exemplary embodiments of the invention (such as those shown in FIGS. 1-3, for example).

In further exemplary embodiments, the design structure 490 may also employ a data format used for the exchange of layout data of integrated circuits and/or symbolic data format (e.g., information stored in a GDSII (GDS2), GL1, OASIS, map files or any other suitable format for storing such design data structures). The design structure 490 may comprise information such as, for example, symbolic data, map files, test data files, design content files, manufacturing data, layout parameters, wires, levels of metal, vias, shapes, data for routing through the manufacturing line and/or any other data required by a manufacturer or other designer/developer to produce a device or structure as described above in accordance with the exemplary embodiments of the invention (such as those shown in FIGS. 1-3, for example). The design structure 490 may then proceed to a stage 495 where, for example, the design structure 490 proceeds to tape-out, is released to manufacturing, is released to a mask house, is sent to another design house and/or is sent back to the customer, as non-limiting examples.

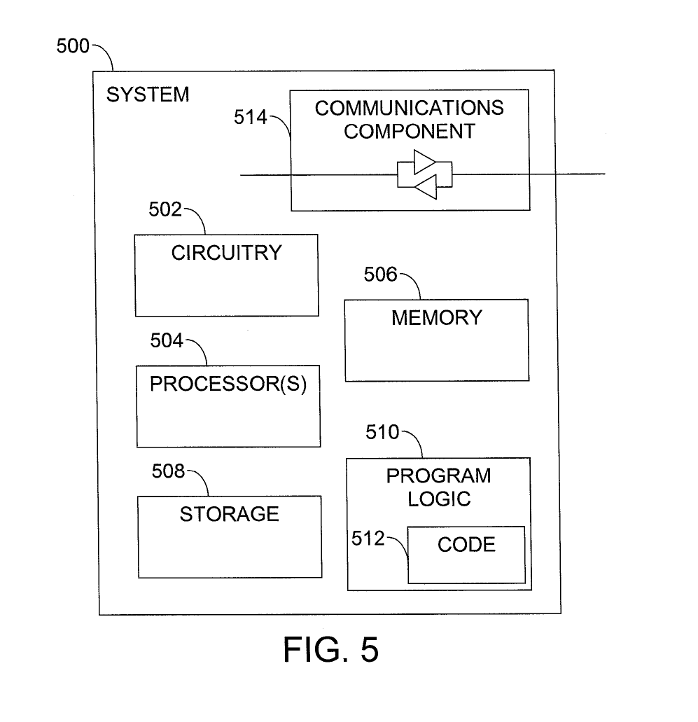

FIG. 5 illustrates a block diagram of an exemplary system 500 in which certain exemplary embodiments may be implemented. In certain exemplary embodiments, the various blocks shown in FIGS. 4 and/or 6 may be implemented, collectively or individually, in accordance with the system 500. The system 500 may include at least one circuitry 502 that may in certain embodiments include at least one processor 504. The system 500 may also include at least one memory 506 (e.g., a volatile memory device), and/or at least one storage 508. The storage 508 may include a non-volatile memory device (e.g., EEPROM, ROM, PROM, RAM, DRAM, SRAM, flash, firmware, programmable logic, etc.), magnetic disk drive, optical disk drive and/or tape drive, as non-limiting examples. The storage 508 may comprise an internal storage device, an attached storage device and/or a network accessible storage device, as non-limiting examples. The system 500 may include at least one program logic 510 including code 512 (e.g., program code) that may be loaded into the memory 506 and executed by the processor 504 and/or circuitry 502. In certain exemplary embodiments, the program logic 510, including the code 512, may be stored in the storage 508. In certain other exemplary embodiments, the program logic 510 may be implemented in the circuitry 502. Therefore, while FIG. 5 shows the program logic 510 separately from the other elements, the program logic 510 may be implemented in the memory 506 and/or the circuitry 502.

The system 500 may include at least one communications component 514 that enables communication with at least one other system, device and/or apparatus. The communications component 514 may include a transceiver configured to send and receive information, a transmitter configured to send information and/or a receiver configured to receive information. As a non-limiting example, the communications component 514 may comprise a modem or network card. The system 500 of FIG. 5 may be embodied in a computer or computer system, such as a desktop computer, a portable computer or a server, as non-limiting examples. The components of the system 500 shown in FIG. 5 may be connected or coupled together using one or more internal buses, connections, wires and/or (printed) circuit boards, as non-limiting examples.

It should be noted that in accordance with the exemplary embodiments of the invention, one or more of the circuitry 502, processor(s) 504, memory 506, storage 508, program logic 510 and/or communications component 514 may store one or more of the various items (e.g., data, files, operations, operational logic, logic) discussed above.

Below are further descriptions of various non-limiting, exemplary embodiments of the invention. The below-described exemplary embodiments are numbered separately for clarity purposes. This numbering should not be construed as entirely separating the various exemplary embodiments since aspects of one or more exemplary embodiments may be practiced in conjunction with one or more other aspects or exemplary embodiments.

(1) In one exemplary embodiment of the invention, a semiconductor structure comprising: a substrate; and at least one layer of silicon overlying the substrate, the at least one layer of silicon comprising at least one active region having at least one device, where a design layout of the at least one active region is in accordance with a plurality of design layout rules comprising: a multiple-fingered device is mapped to be a symmetric device or an asymmetric body-tied device; a single-fingered device is mapped to be an asymmetric device; an active region having a single-fingered device is entirely source-up or entirely source-down; and an active region falls into one of two categories: a first category where the active region does not include any symmetric devices or a second category where the active region does not include any asymmetric devices.

A semiconductor structure as above, where the at least one device comprises at least one field effect transistor. A semiconductor structure as in any above, where the at least one device comprises at least one n-type field effect transistor. A semiconductor structure as in any above, where the at least one device comprises at least one p-type field effect transistor. A semiconductor structure as in any above, where the semiconductor structure comprises a silicon-on-insulator. A semiconductor structure as in any above, where the asymmetric device that the single-fingered device is mapped to comprises a body-tied asymmetric device which behaves as a symmetric device. A semiconductor structure as in any above, where the body-tied asymmetric device comprises a body-tied asymmetric field effect transistor.

A semi-conductor structure as in any above, where a multiple-fingered device is mapped to be one of a symmetric device or an asymmetric body-tied device. A semi-conductor structure as in any above, where a multiple-fingered device is not mapped to be a symmetric device and an asymmetric body-tied device. A semi-conductor structure as in any above, where a multiple-fingered device is mapped to be a symmetric device or an asymmetric body-tied device but not both. A semi-conductor structure as in any above, where an active area may include only one of symmetric devices and asymmetric body-tied devices.

A semiconductor structure as in any above, further comprising one or more further aspects of the exemplary embodiments of the invention as described herein.

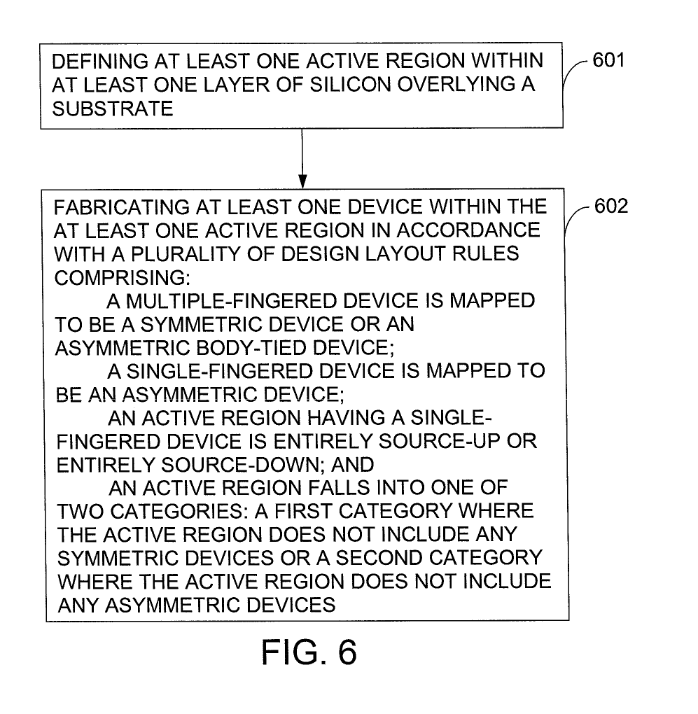

(2) In another exemplary embodiment, and as shown in FIG. 6, a method for forming a semiconductor structure, comprising: defining at least one active region within at least one layer of silicon overlying a substrate (601); and fabricating at least one device within the at least one active region in accordance with a plurality of design layout rules comprising: a multiple-fingered device is mapped to be a symmetric device or an asymmetric body-tied device; a single-fingered device is mapped to be an asymmetric device; an active region having a single-fingered device is entirely source-up or entirely source-down; and an active region falls into one of two categories: a first category where the active region does not include any symmetric devices or a second category where the active region does not include any asymmetric devices (602).

A method as above, where the at least one device comprises at least one field effect transistor. A method as in any above, where the at least one device comprises at least one n-type field effect transistor. A method as in any above, where the at least one device comprises at least one p-type field effect transistor. A method as in any above, where the semiconductor structure comprises a silicon-on-insulator.

A method as in any above, further comprising one or more further aspects of the exemplary embodiments of the invention as described herein.

A semiconductor structure produced according to the process (e.g., method) described above. A semiconductor structure as above, where the at least one device comprises at least one field effect transistor. A semiconductor structure as in any above, where the at least one device comprises at least one n-type field effect transistor and/or at least one p-type field effect transistor. A semiconductor structure as in any above, where the semiconductor structure comprises a silicon-on-insulator.

A semiconductor structure as in any above, further comprising one or more further aspects of the exemplary embodiments of the invention as described herein.

(3) In another exemplary embodiment, a design structure tangibly embodied in a machine readable medium (e.g., a computer readable medium, a computer readable storage medium, a memory, a storage device, a computer readable memory medium) for designing, manufacturing or testing an integrated circuit, the design structure comprising: a substrate; and at least one layer of silicon overlying the substrate, the at least one layer of silicon comprising at least one active region having at least one device, where a design layout of the at least one active region is in accordance with a plurality of design layout rules comprising: a multiple-fingered device is mapped to be a symmetric device or an asymmetric body-tied device; a single-fingered device is mapped to be an asymmetric device; an active region having a single-fingered device is entirely source-up or entirely source-down; and an active region falls into one of two categories: a first category where the active region does not include any symmetric devices or a second category where the active region does not include any asymmetric devices.

The design structure as above, wherein the design structure comprises a netlist. The design structure as in any above, wherein the design structure resides on a storage medium as a data format used for the exchange of layout data of integrated circuits. The design structure as in any above, wherein the design structure resides in a programmable gate array. The design structure as in any above, further comprising one or more aspects of the exemplary embodiments of the invention as described in further detail herein.

(4) In another exemplary embodiment, a design structure readable by a machine used in design, manufacture or simulation of an integrated circuit, the design structure comprising: a substrate; and at least one layer of silicon overlying the substrate, the at least one layer of silicon comprising at least one active region having at least one device, where a design layout of the at least one active region is in accordance with a plurality of design layout rules comprising: a multiple-fingered device is mapped to be a symmetric device or an asymmetric body-tied device; a single-fingered device is mapped to be an asymmetric device; an active region having a single-fingered device is entirely source-up or entirely source-down; and an active region falls into one of two categories: a first category where the active region does not include any symmetric devices or a second category where the active region does not include any asymmetric devices.

The design structure as in any above, further comprising one or more aspects of the exemplary embodiments of the invention as described in further detail herein.

(5) In another exemplary embodiment, hardware description language (HDL) design structure encoded on a machine-readable data storage medium, said HDL design structure comprising elements that, when processed in a computer-aided design system, generate a machine-executable representation of a semiconductor structure, wherein said semiconductor structure comprises: a substrate; and at least one layer of silicon overlying the substrate, the at least one layer of silicon comprising at least one active region having at least one device, where a design layout of the at least one active region is in accordance with a plurality of design layout rules comprising: a multiple-fingered device is mapped to be a symmetric device or an asymmetric body-tied device; a single-fingered device is mapped to be an asymmetric device; an active region having a single-fingered device is entirely source-up or entirely source-down; and an active region falls into one of two categories: a first category where the active region does not include any symmetric devices or a second category where the active region does not include any asymmetric devices.

The HDL design structure as in any above, further comprising one or more aspects of the exemplary embodiments of the invention as described in further detail herein.

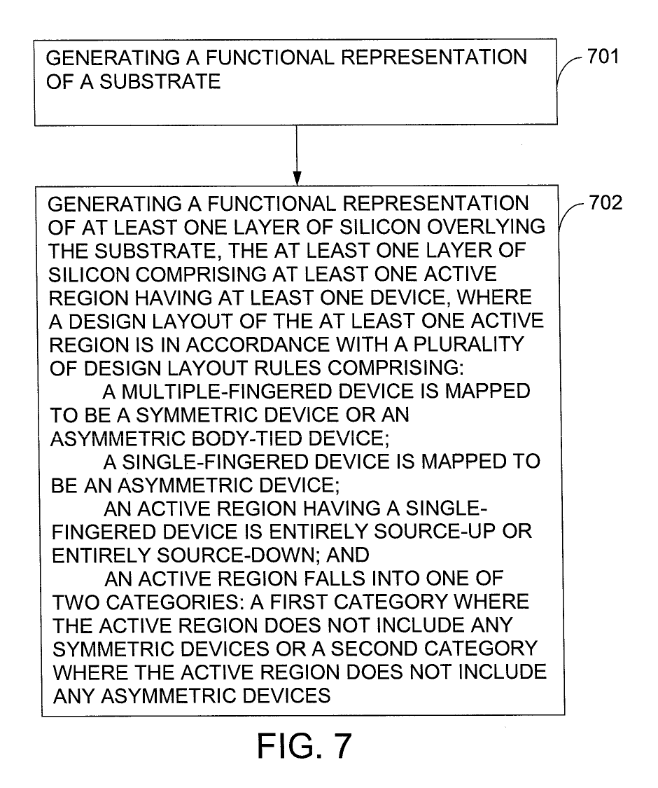

(6) In another exemplary embodiment, and as shown in FIG. 7, a method in a computer-aided design system for generating a functional design model of a semiconductor structure, said method comprising: generating a functional representation of a substrate (701); and generating a functional representation of at least one layer of silicon overlying the substrate (702), the at least one layer of silicon comprising at least one active region having at least one device, where a design layout of the at least one active region is in accordance with a plurality of design layout rules comprising: a multiple-fingered device is mapped to be a symmetric device or an asymmetric body-tied device; a single-fingered device is mapped to be an asymmetric device; an active region having a single-fingered device is entirely source-up or entirely source-down; and an active region falls into one of two categories: a first category where the active region does not include any symmetric devices or a second category where the active region does not include any asymmetric devices.

The method as in any above, further comprising one or more aspects of the exemplary embodiments of the invention as described in further detail herein.

(7) In another exemplary embodiment, a computer readable medium (e.g., a computer readable storage medium) tangibly embodying (e.g., storing, encoded with) a design structure (e.g., a design data structure) readable by a machine (e.g., a processor, a computer) (e.g., used in design, manufacture or simulation of an integrated circuit), the design structure comprising information representative of (e.g., corresponding to, indicative of) at least one semiconductor structure having at least one active region (e.g., delineated by at least one STI) with at least one device, (e.g., where the design structure is for use by the machine in design, manufacture or simulation of an integrated circuit) where a design layout of the at least one active region is in accordance with a plurality of design layout rules comprising: a multiple-fingered device is mapped to be a symmetric device or an asymmetric body-tied device; a single-fingered device is mapped to be an asymmetric device; an active region having a single-fingered device is entirely source-up or entirely source-down; and an active region falls into one of two categories: a first category where the active region does not include any symmetric devices or a second category where the active region does not include any asymmetric devices.

The computer readable medium as in any above, further comprising one or more aspects of the exemplary embodiments of the invention as described in further detail herein.

The exemplary embodiments of the invention as discussed herein may be implemented in conjunction with a program storage device (e.g., at least one memory) readable (e.g., by a machine and/or a computer) (e.g., a computer readable storage medium), tangibly embodying (e.g., storing) a program of instructions (e.g., a program, a computer program, program code) executable by a/the machine for performing operations. The operations comprise steps of utilizing (e.g., practicing) the exemplary embodiments of the invention or steps of the method.

The exemplary embodiments of the invention as discussed herein further may be implemented in conjunction with a program storage device (e.g., at least one memory) readable (e.g., by a machine and/or a computer) (e.g., a computer readable storage medium), tangibly embodying (e.g., storing) a data structure (e.g., a design structure, a design layout structure). As a non-limiting example, the data structure may include information, data, values, rules and/or guidelines (e.g., design layout for a device, design layout for a semiconductor, design layout for a semiconductor device) in accordance with the exemplary embodiments of the invention.

The blocks shown in FIGS. 4 and 6 further may be considered to correspond to one or more functions and/or operations that are performed by one or more components, circuits, chips, apparatus, processors, computer programs and/or function blocks. Any and/or all of the above may be implemented in any practicable solution or arrangement that enables operation in accordance with the exemplary embodiments of the invention as described herein.

In addition, the arrangement of the blocks depicted in FIGS. 4, 6 and 7 should be considered merely exemplary and non-limiting. It should be appreciated that the blocks shown in FIGS. 4, 6 and 7 may correspond to one or more functions and/or operations that may be performed in any order (e.g., any suitable, practicable and/or feasible order) and/or concurrently (e.g., as suitable, practicable and/or feasible) so as to implement one or more of the exemplary embodiments of the invention. In addition, one or more additional functions, operations and/or steps may be utilized in conjunction with those shown in FIGS. 4, 6 and 7 so as to implement one or more further exemplary embodiments of the invention.

That is, the exemplary embodiments of the invention shown in FIGS. 4, 6 and 7 may be utilized, implemented or practiced in conjunction with one or more further aspects in any combination (e.g., any combination that is suitable, practicable and/or feasible) and are not limited only to the steps, blocks, operations and/or functions shown in FIGS. 4, 6 and 7.

The flowchart and block diagrams in FIGS. 4, 6 and 7 illustrate the architecture, functionality, and operation of possible exemplary implementations of systems, methods, computer program products and data structures according to various exemplary embodiments of the present invention. In this regard, each block in the flowchart or block diagrams may represent a module, segment or portion of code which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions, as non-limiting examples.

As will be appreciated by one skilled in the art, aspects of the exemplary embodiments of the invention may be embodied as a system, method, computer program product, data structure, design structure and/or design layout structure, as non-limiting examples. Accordingly, aspects of the exemplary embodiments of the invention may take the form of an entirely hardware embodiment, an entirely software embodiment (including firmware, resident software, micro-code, etc.) or an embodiment combining software and hardware aspects that may all generally be referred to herein as a “circuit,” “module” or “system,” as non-limiting examples. Furthermore, aspects of the exemplary embodiments of the invention may take the form of a computer program product embodied in one or more computer readable medium(s) having computer readable program code embodied thereon. In addition, aspects of the exemplary embodiments of the invention may take the form of a computer readable medium having information and/or data stored thereon.

Any combination of one or more computer readable medium(s) may be utilized. The computer readable medium may be a computer readable signal medium or a computer readable storage medium. As non-limiting examples, a computer readable storage medium may comprise one or more of: an electronic, magnetic, optical, electromagnetic, infrared, or semiconductor system, apparatus, or device, or any suitable combination of the foregoing. More specific non-limiting examples of a computer readable storage medium include: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that is configured/operable to contain or store a program for use by or in connection with an instruction execution system, apparatus, or device (e.g., a computer or a processor).

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including, but not limited to: wireless, wireline, wired, optical fiber cable, RF, or any suitable combination of the foregoing.

Computer program code for carrying out operations for aspects of the exemplary embodiments of the invention may be written in any combination of one or more programming languages, including an object oriented programming language such as Java, Smalltalk or C++ and conventional procedural programming languages, such as the “C” programming language or similar programming languages, as non-limiting examples. The program code may execute entirely on the user's computer, partly on the user's computer, as a stand-alone software package, partly on the user's computer and partly on a remote computer or entirely on the remote computer or server, as non-limiting examples. In the latter scenario, the remote computer may be connected to the user's computer through any type of network, including a local area network (LAN) or a wide area network (WAN), or the connection may be made to an external computer (for example, through the Internet using an Internet Service Provider), as non-limiting examples.

Aspects of the exemplary embodiments of the invention are described herein with reference to flowchart illustrations and/or block diagrams of methods, apparatus (systems) and computer program products according to various exemplary embodiments of the invention. It will be understood that each block of the flowchart illustrations and/or block diagrams, and combinations of blocks in the flowchart illustrations and/or block diagrams, can be implemented by computer program instructions, as a non-limiting examples. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks, as non-limiting examples.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks (e.g., exemplary embodiments of the invention).

Any use of the terms “connected,” “coupled” or variants thereof should be interpreted to indicate any such connection or coupling, direct or indirect, between the identified elements. As a non-limiting example, one or more intermediate elements may be present between the “coupled” elements. The connection or coupling between the identified elements may be, as non-limiting examples, physical, electrical, magnetic, logical or any suitable combination thereof in accordance with the described exemplary embodiments. As non-limiting examples, the connection or coupling may comprise one or more printed electrical connections, wires, cables, mediums or any suitable combination thereof.

Generally, various exemplary embodiments of the invention can be implemented in different mediums, such as software, hardware, logic, special purpose circuits or any combination thereof. As a non-limiting example, some aspects may be implemented in software which may be run on a computing device, while other aspects may be implemented in hardware.

The foregoing description has provided by way of exemplary and non-limiting examples a full and informative description of the best method and apparatus presently contemplated by the inventors for carrying out the invention. However, various modifications and adaptations may become apparent to those skilled in the relevant arts in view of the foregoing description, when read in conjunction with the accompanying drawings and the appended claims. However, all such and similar modifications will still fall within the scope of the teachings of the exemplary embodiments of the invention.

Furthermore, some of the features of the preferred embodiments of this invention could be used to advantage without the corresponding use of other features. As such, the foregoing description should be considered as merely illustrative of the principles of the invention, and not in limitation thereof.

What is claimed is:

1. A semiconductor structure comprising:
a substrate; and
at least one layer of silicon overlying the substrate, the at least one layer of silicon comprising at least one active region having at least one device, where a design layout of the at least one active region is in accordance with a plurality of design layout rules comprising:
a multiple-fingered device is mapped to be a symmetric device or an asymmetric body-tied device;
a single-fingered device is mapped to be an asymmetric device;
an active region having a single-fingered device is entirely source-up or entirely source-down; and
an active region falls into one of two categories: a first category where the active region does not include any symmetric devices or a second category where the active region does not include any asymmetric devices.

2. The semiconductor structure of claim 1, where the at least one device comprises at least one field effect transistor.

3. The semiconductor structure of claim 1, where the at least one device comprises at least one n-type field effect transistor.

4. The semiconductor structure of claim 1, where the at least one device comprises at least one p-type field effect transistor.

5. The semiconductor structure of claim 1, where the semiconductor structure comprises a silicon-on-insulator.

6. A method for forming a semiconductor structure, comprising:
defining at least one active region within at least one layer of silicon overlying a substrate; and
fabricating at least one device within the at least one active region in accordance with a plurality of design layout rules comprising:
a multiple-fingered device is mapped to be a symmetric device or an asymmetric body-tied device;
a single-fingered device is mapped to be an asymmetric device;
an active region having a single-fingered device is entirely source-up or entirely source-down; and
an active region falls into one of two categories: a first category where the active region does not include any symmetric devices or a second category where the active region does not include any asymmetric devices.

7. The method of claim 6, where the at least one device comprises at least one field effect transistor.

8. The method of claim 6, where the at least one device comprises at least one n-type field effect transistor.

9. The method of claim 6, where the at least one device comprises at least one p-type field effect transistor.

10. The method of claim 6, where the semiconductor structure comprises a silicon-on-insulator.

11. A semiconductor structure produced according to the method of claim 6.

12. The semiconductor structure of claim 11, where the at least one device comprises at least one field effect transistor.

13. The semiconductor structure of claim 11, where the at least one device comprises at least one n-type field effect transistor or at least one p-type field effect transistor.

14. The semiconductor structure of claim 11, where the semiconductor structure comprises a silicon-on-insulator.

15. A computer readable storage medium storing a design structure readable by a machine, the design structure comprising information representative of at least one semiconductor structure having at least one active region with at least one device, where the design structure is for use by the machine in design, manufacture or simulation of an integrated circuit, where a design layout of the at least one active region is in accordance with a plurality of design layout rules comprising:
a multiple-fingered device is mapped to be a symmetric device or an asymmetric body-tied device;
a single-fingered device is mapped to be an asymmetric device;
an active region having a single-fingered device is entirely source-up or entirely source-down; and
an active region falls into one of two categories: a first category where the active region does not include any symmetric devices or a second category where the active region does not include any asymmetric devices.

16. The computer readable storage medium of claim 15, where the at least one device comprises at least one field effect transistor.

17. The computer readable storage medium of claim 15, where the at least one device comprises at least one n-type field effect transistor or at least one p-type field effect transistor.

18. The computer readable storage medium of claim 15, where the semiconductor structure comprises a silicon-on-insulator.

19. The computer readable storage medium of claim 15, where the design structure comprises a netlist.

20. The computer readable storage medium of claim 15, where the design structure is in a data format that is used for exchange of layout data of integrated circuits.
